(19) United States
(12) Patent Application Publication
(10) Pub. No.: US 2015/0249450 A1
(43) Pub. Date: Sep. 3, 2015

(54) BILATERAL SWITCH

(71) Applicants: Mohamed Sirajuddin, Tamil Nadu (IN); Kamran Chida, Auckland (NZ)

(72) Inventors: Mohamed Sirajuddin, Tamil Nadu (IN); Kamran Chida, Auckland (NZ)

(21) Appl. No.: 14/385,310

(22) PCT Filed: Mar. 14, 2012
(86) PCT No.: PCT/NZ2012/000037

§ 371 Date: May 6, 2015

(51) Int. Cl. H03K 17/687; H03K 17/689

(52) U.S. Cl. CPC H03K 17/6874; H03K 17/689

(57) ABSTRACT

A bilateral switch derives internal power for the operation of the switch control circuitry from a converter powered by the input signal, whether the input is AC or DC, and also operates the internal voltage isolated circuits powered by this from the input signal. The internal circuitry operates a pair of similar FET switches switching power on and off between their drain connections, relying on a reverse protection diode across the FETs to allow passage of either AC current or DC current in either direction.

### TECHNICAL FIELD

The invention generally relates to electronic bilateral switches.

More particularly the invention relates to bilateral switches operated by a control input.

### BACKGROUND ART

Electronic or solid state switches are well known and are normally produced as suitable for AC or for DC typically with a DC control voltage applied. Operation of such switches at greater than a rate in the low kilohertz range requires measures which produce costly switches. Switches which can handle either AC input or DC input are even more costly to produce.

Therefore a need exists for a solution to the problem of providing a solid state switch which can switch a large current at a high rate and which meets cost requirements.

The present invention provides a solution to this and other problems which offers advantages over the prior art or which will at least provide the public with a useful choice.

All references, including any patents or patent applications cited in this specification are hereby incorporated by reference. No admission is made that any reference constitutes prior art. The discussion of the references states what their authors assert, and the applicants reserve the right to challenge the accuracy and pertinency of the cited documents. It will be clearly understood that, although a number of prior art publications are referred to herein; this reference does not constitute an admission that any of these documents form part of the common general knowledge in the art, in New Zealand or in any other country.

### SUMMARY OF THE INVENTION

In one exemplification the invention consists in a bilateral switch having a converter which internally converts an input signal to provide an electrically isolated power supply, the electrically isolated power supply connected to and providing current to a low current switch operated by the input signal via an electrically isolated connection, the low current switch connected to and operating at least a totem pole pair of semiconductor devices also powered from the electrically isolated power supply, the at least one totem pole pair of semiconductor devices connected to and operating at least one similar pair of FET (Field Effect Transistor) transistor devices connected to bilaterally switch current to a circuit to be switched on or off in response to the input signal.

Preferably the input signal is applied to an IRLED (Infra-Red Light Emitting Diode) of an optocoupler in which the optocoupler output device is the low current switch.

Preferably the input signal is applied as the power source of an oscillator whose isolated output provides the electrically isolated power supply.

Preferably the totem pole pair of semiconductor devices is connected to the conjoined gates of two similar MOSFET (Metal Oxide Semiconductor Field Effect Transistor) transistors forming the pair of FET transistor devices, that the sources of the MOSFETs are connected together and that the circuit to be switched is connected to the drain of each MOSFET and a reverse protection diode is connected across the drain and source of each MOSFET.

Preferably each MOSFET has an internal diode connected across the drain and source.

Preferably the current path for the circuit to be switched on and off extends through a biased on MOSFET and the reverse protection diode across the drain and source of the other MOSFET.

Preferably the input signal is either AC or DC.

Preferably the current in the switched circuit is either AC or DC.

In an alternative embodiment the invention consists in a method of providing a bilateral switch by deriving an electrically isolated power supply from a switch input signal, operating an electrically isolated low power switch powered from the power supply, operating from the electrically isolated low power switch at least a pair of totem pole semiconductor devices powered from the electrically isolated power supply, operating from the at least one pair of totem pole semiconductor devices at least one pair of FET devices, the FET devices switching current through a connected circuit on or off in response to the input signal.

Preferably the totem pole pair of semiconductor devices is connected to the conjoined gates of two similar MOSFET transistors forming the pair of FET transistor devices, that the sources of the MOSFETs are connected together and that the circuit to be switched is connected to the drain of each MOSFET and a reverse protection diode is connected across the drain and source of each MOSFET.

These and other features of as well as advantages which characterise the present invention will be apparent upon reading of the following detailed description and review of the associated drawings.

### BRIEF DESCRIPTION OF THE DRAWINGS

FIG. 1 is a circuit diagram of the bilateral switch of the invention.

### DESCRIPTION OF THE INVENTION

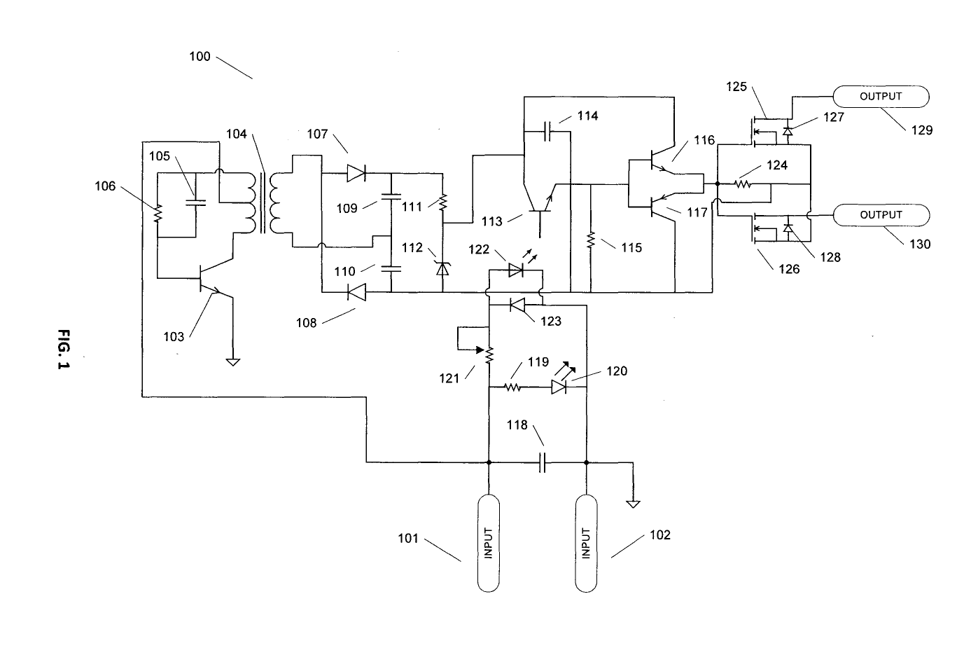

Referring now to FIG. 1 a bilateral switch circuit 100 is shown. The circuit includes input terminals 101, 102 with a noise frequency filter capacitor 118 across them and connecting to a converter made up of transformer 104, transistor 103 and a tuned feedback loop of resistor 106 and capacitor 105 and the inductance of transformer 104. The voltage on the output side of the transformer is rectified in voltage doubling diodes 107, 108. The converter operates at between 100 KHz and 300 KHz with the output of from 20 to 40 volts being smoothed by capacitors 109, 110 before being limited to 9 volts after passing through resistor 111 by zener diode 112 and held in storage capacitor 114.

The input terminals 101, 102 also supply an IRLED 122 forming part of a optoelectronic coupling pair of IRLED diode 122 and phototransistor 113, which may be implemented as an integrated optocoupler. An LED 120, with current limited by resistor 119, provides an indication when an input signal is present. A preset resistor 121 is provided to set the standing current in the optocoupler IRLED for best frequency response. In the other polarity of input diode 123 limits the voltage across the optocoupler IRLED.

When optocoupler IRLED 122 is off transistor 113 is non-conductive, allowing resistor 115 to pull down the bases of totem pole connected transistors 116, 117. This in turn pulls the emitters of transistors 116, 117 low and pulls the gates of N-channel MOSFET transistors 125 and 126 low, rendering them non-conductive. As a result no current flows between output terminals 129, 130.

When optocoupler IRLED 122 is provided with voltage from the input terminals 101, 102 it illuminates transistor 113 and brings it into conduction. This raises the voltage at the bases of totem pole transistors 116, 117, in turn raising the emitter voltages. This in turn biases on the gates of similar MOSFETs 125, 126, bringing them into conduction and providing a path between output terminals 129, 130.

Because transistors 125 and 126 are connected to the output terminals in opposition one of the MOSFETs will always have a drain negative with respect to the other and to its own source terminal, and thus although it may be biased on it cannot conduct in the normal manner. Instead the protective diode 127 or 128 of the respective transistor will conduct. This allows a circuit to be established between the output terminals regardless of the polarity at the output terminals. The conduction voltage across the protective diode is greater than the forward voltage across a fully conductive MOSFET because it is normally a parasitic transistor in the MOSFET which will give a higher power dissipation in the reverse polarity MOSFET than in the forward polarity MOSFET.

The input voltage signal may be AC or DC but must be sufficient to both power the optocoupler and the totem pole transistor pair as well as driving the gate capacitance of the MOSFET transistors. The current through the optocoupler IRLED is adjusted with preset resistor 121 for best frequency response at the MOSFET, that is, for the highest frequency at which the MOSFETs will still switch on and off without exceeding the power dissipation rating of any heatsink.

It should be noted that with an AC input at terminals 101, 102 the converter will be running only for the positive half cycles, however this should still provide sufficient power to operate the MOSFET switching circuitry which will have a reasonably constant rectified supply and will be switched by the optocoupler.

Totem pole connected transistors 116, 117 provide a sufficiently low resistance current path when on to quickly discharge the gate capacitance, thereby providing a quick turnoff of the active MOSFET.

The bilateral switch shown will operate with either pulsed AC or DC at the input, and with either AC or DC at the output. It provides a maximum switching frequency which is normally between 10 KHz and 20 KHZ with commercially available components and can provide a controlled current of up to 80 amps with such components.

The components used in the embodiment are described below in Table 1:

TABLE 1

| Reference | Component | Value or type |
|---|---|---|
| 103 | Transistor | MJE13003 |
| 105 | Capacitor | 100 pF |
| 106 | Resistor | 22 KΩ |
| 107, 108 | Diode | 1N4148 |
| 109, 110 | Capacitor | .01 μF |
| 111 | Resistor | 1 KΩ |
| 112 | Zener diode | 9 V |
| 113, 122 | Optocoupler | 4N25 |
| 114 | Capacitor | 1 μF |
| 115 | Resistor | 10 KΩ |
| 116 | Transistor | BC548 |
| 117 | Transistor | BC558 |
| 118 | Capacitor | .01 μF |
| 119 | Resistor | 4 KΩ |
| 120 | LED | |
| 121 | Variable resistor | 10 KΩ |
| 123 | Diode | 1N4148 |
| 124 | Resistor | 10 KΩ |
| 125, 126 | MOSFET | 1XFX80N50P |
| 127, 128 | Protective diode | Integral with MOSFET |

The components used are all easily available and cheap and the overall current rating is a property of the MOSFET type used and easily variable.

While the implementation described uses an optocoupler to drive the low power switches implemented as a totem pole pair other methods of deriving the same drive signals are optional, for instance a suitably programmed microprocessor may be used. Similarly the derivation of the isolated power supply from the input signal may be differently provided in order to be totally polarity independent.

Similarly while the circuit describes the use of two similar MOSFET transistors the switch may equally use any even number of such transistors with half having the drain connected to each of the output terminals. The totem pole pair may require multiplication to provide adequate MOSFET drain capacitance drive.

It is to be understood that even though numerous characteristics and advantages of the various embodiments of the present invention have been set forth in the foregoing description, together with details of the structure and functioning of various embodiments of the invention, this disclosure is illustrative only, and changes may be made in detail so long as the functioning of the invention is not adversely affected. For example the particular elements of the bilateral switch may vary dependent on the particular application for which it is used without variation in the spirit and scope of the present invention.

In addition, although the preferred embodiments described herein are directed to a bilateral switch for use in controlling a current within the capabilities of the FET transistors of the system, it will be appreciated by those skilled in the art that variations and modifications are possible within the scope of the appended claims.

### INDUSTRIAL APPLICABILITY

The bilateral switch of the invention is used in the switching of AC or DC power in numerous industrial applications, for instance in phase correction circuitry and are employed in the electrical industry. The present invention is therefore industrially applicable.

1. A bilateral switch having a converter which internally converts an input signal to provide an electrically isolated power supply, the electrically isolated power supply connected to and providing current to a low current switch operated by the input signal via an electrically isolated connection, the low current switch connected to and operating at least a totem pole pair of semiconductor devices also powered from the electrically isolated power supply, the at least one totem pole pair of semiconductor devices connected to and operating at least one similar pair of FET transistor devices connected to bilaterally switch current to a circuit to be switched on or off in response to the input signal.

2. A bilateral switch as claimed in claim 1 wherein the input signal is applied to an LED of an optocoupler in which the optocoupler output device is the low current switch.

3. A bilateral switch as claimed in claim 1 wherein the input signal is applied as the power source of an oscillator whose isolated output provides the electrically isolated power supply.

4. A bilateral switch as claimed in claim 1 wherein the totem pole pair of semiconductor devices is connected to the conjoined gates of two similar MOSFET transistors forming the pair of FET transistor devices, that the sources of the MOSFETs are connected together and that the circuit to be switched is connected to the drain of each MOSFET and a reverse protection diode is connected across the drain and source of each MOSFET.

5. A bilateral switch as claimed in claim 4 wherein each MOSFET has an internal diode connected across the drain and source.

6. A bilateral switch as claimed in claim 5 wherein the current path for the circuit to be switched on and off extends through a biased on MOSFET and the reverse protection diode across the drain and source of the other MOSFET.

7. A bilateral switch as claimed in claim 1 wherein the input signal is either pulsed AC or DC.

8. A bilateral switch as claimed in claim 1 wherein the current in the switched circuit is either AC or DC.

9. A method of providing a bilateral switch by deriving an electrically isolated power supply from a switch input signal, operating an electrically isolated low power switch powered from the power supply, operating from the electrically isolated low power switch at least a pair of totem pole semiconductor devices powered from the power supply, operating from the at least one pair of totem pole semiconductor devices at least one pair of similar FET devices, the FET devices switching current through a connected circuit on or off in response to the input signal.

10. A method of providing a bilateral switch as claimed in claim 9 wherein the totem pole pair of semiconductor devices is connected to the conjoined gates of two similar MOSFET transistors forming the pair of FET transistor devices, that the sources of the MOSFETs are connected together and that the connected circuit to be switched is connected to the drain of each MOSFET and a reverse protection diode is connected across the drain and source of each MOSFET such that the circuit to be switched is switched on when the MOSFETs are biased on irrespective of circuit polarity or input polarity.
